(19) United States
(12) Patent Application Publication
(10) Pub. No.: US 2007/0298548 A1
(43) Pub. Date: Dec. 27, 2007

(54) ACTIVE MATRIX DISPLAY

(75) Inventors: Hitoshi NAGATA, Tokyo (JP); Takuji Imamura, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/758,925

(22) Filed: Jun. 6, 2007

(30) Foreign Application Priority Data
Jun. 12, 2006 (JP) 2006-162696

(51) Int. Cl. H01L 21/84

(52) U.S. Cl. 438/149

(57) ABSTRACT

The active matrix display includes a polysilicon layer including a source region, a drain region and a channel region and placed on an insulating substrate, a gate insulating layer placed on the polysilicon layer, a gate electrode placed on the gate insulating layer, an interlayer insulating layer placed on the gate electrode, and a wiring layer connected to the source region and the drain region through a contact hole of the interlayer insulating layer. A first pixel electrode on the insulating substrate, the gate insulating layer, and a capacitor upper electrode placed in the same layer as the gate electrode constitute a capacitor.

### BACKGROUND OF THE INVENTION

1. Field of the Invention

The present invention relates to an active matrix display using a polysilicon TFT.

2. Description of Related Art

With the recent intensive development of highly sophisticated information society and rapid proliferation of multimedia systems, displays such as liquid crystal displays (LCD) and organic electro luminescence (EL) displays become increasingly important. As a driving method of pixels in such displays, active matrix using thin film transistors (TFT) arranged in an array are widely adopted. Active matrix type displays employ a TFT array substrate on which TFTs are arranged in an array.

A TFT used in such displays typically has a MOS structure with a silicon film. The silicon film maybe an amorphous silicon (a-Si) film or a polysilicon (p-Si) film. The carrier mobility of polysilicon is about two orders of magnitude greater than that of a-Si, thus enhancing the performance of a TFT. On the other hand, manufacturing of polysilicon requires a temperature of as high as 1000° C. and thus needs to use a quartz glass substrate with a melting point of 1000° C. or above as an insulating substrate, which causes a high manufacturing cost. However, with the advent of a low-temperature process, a low-temperature polysilicon (LTPS) TFT that overcomes the above drawback has been introduced, contributing to the development of larger-size and higher-definition displays.

The LTPS TFT typically includes a silicon layer having a source region, a drain region and a channel region that is placed on an insulating substrate, a gate insulating layer that is placed on the silicon layer, and a gate electrode that is placed on the gate insulating layer. On the gate electrode, an interlayer insulating layer area to cover the gate electrode and the gate insulating layer is located, and a line for connection with the drain region and the gate electrode is placed thereon. Further, an upper insulating layer to cover the line and the interlayer insulating layer are placed on the line.

With the use of the LTPS TFT for a circuit in the vicinity of a display, it is possible to reduce the use of an integrated circuit (IC) and an IC placement plate to thereby simplify the structure around the display, thus achieving a highly reliable display with a narrow frame area. Further, it is possible in a liquid crystal display to reduce the capacity of a switching transistor of each pixel and also reduce the area of a storage capacitor that is connected to the drain side, thereby achieving a high-resolution, high-aperture-ratio liquid crystal display. Therefore, the LTPS TFT is dominant in high-resolution liquid crystal displays such as QVGA (240×320 pixels) and VGA (480×640 pixels) with a small panel used for mobile phones or the like. The LTPS TFT has a significant advantage in performance over the a-Si.

Japanese Unexamined Patent Application Publication No. 10-153801 (Yudasaka) discloses an example of an active matrix display utilizing the advantages of the LTPS TFT, which is configured to directly connect a drain region of a TFT and a capacitor lower electrode. The capacitor in this configuration may have a thin gate insulating layer, which is the characteristics of the LTPS TFT. This reduces the occupation area of the capacitor to increase the aperture ratio of pixels. This is one of the causes of the fact that the LTPS TFT is more suited for high resolution than the a-Si.

However, the LTPS TFT requires more steps in the manufacturing process than the a-Si. Although the patterning of an a-Si TFT LCD requires five steps, that of an LTPS TFT LCD requires eight steps. The three additional steps required for the patterning of the LTPS TFT LCD are as follows:
1. A step of selective doping for forming a P-type layer in a CMOS structure;
2. A step of doping for reducing the resistance of a polysilicon layer for a lower electrode of a storage capacitor or a step of forming a metal electrode for a lower electrode; and
3. A step of forming a contact hole for source and drain lines.

The three additional patterning steps largely affect the productivity, and the production costs of an LTPS TFT LCD increases by the amount larger than the amount of cost reduction of parts such as an IC and an IC placement plate, which is an advantage of the LTPS TFT LCD. As a result, the product competitiveness of an LTPS TFT LCD is lower than that of an s-Si TFT LCD. Further, in the display disclosed in Yudasaka, a source line placed in a source region and a pixel electrode are formed in the same layer in order to reduce the number of patterning steps. However, if the source line and the pixel electrode are in the same layer, a DC voltage is constantly applied to a liquid crystal layer because of a difference in average voltage between the source line and the pixel electrode. This can lead to a decrease in reliability of displays.

The present invention has been accomplished to solve the above problems and an object of the present invention is thus to provide an active matrix display that requires fewer manufacturing steps without sacrificing the advantages of an LTPS TFT LCD.

### SUMMARY OF THE INVENTION

According to one aspect of the present invention, there is provided an active matrix display including an insulating substrate, a polysilicon layer including a source region, a drain region and a channel region and placed on the insulating substrate, a gate insulating layer placed on the polysilicon layer, a gate electrode placed on the gate insulating layer, an interlayer insulating layer placed on the gate electrode, a wiring layer connected to the source region and the drain region through a contact hole of the interlayer insulating layer, a first pixel electrode placed on the insulating substrate, and an upper electrode placed in the same layer as the gate electrode, wherein the first pixel electrode, the gate insulating layer and the upper electrode constitute a capacitor.

The present invention provides an active matrix display that permits designing and manufacturing of pixels in various layouts with fewer manufacturing steps.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plan view showing an active matrix display according to a first embodiment of the present invention;

FIG. 2A is a cross-sectional view showing the structure of a TFT and a capacitor as a part of the active matrix display according to the first embodiment of the present invention;

FIG. 2B is a cross-sectional view showing the structure of a TFT and a capacitor as a part of the active matrix display according to the first embodiment of the present invention;

FIG. 3A is a cross-sectional view showing the structure of a TFT and a capacitor as a part of the active matrix display according to a second embodiment of the present invention;

FIG. 3B is a cross-sectional view showing the structure of a TFT and a capacitor as a part of the active matrix display according to the second embodiment of the present invention;

FIG. 4A is a cross-sectional view showing the structure of a TFT and a capacitor as a part of the active matrix display according to a third embodiment of the present invention;

FIG. 4B is a cross-sectional view showing the structure of a TFT and a capacitor as a part of the active matrix display according to the third embodiment of the present invention;

FIG. 5 is a cross-sectional view showing the structure of a TFT and a capacitor as a part of the active matrix display according to a fourth embodiment of the present invention;

FIG. 6 is a cross-sectional view showing the structure of a TFT and a capacitor as a part of the active matrix display according to a fifth embodiment of the present invention; and

FIG. 7 is a cross-sectional view showing the structure of a TFT and a capacitor as a part of the active matrix display according to a seventh embodiment of the present invention.

### DESCRIPTION OF THE PREFERRED EMBODIMENTS

An active matrix display according to embodiments of the present invention enables the reduction of the patterning steps of an LTPS TFT to increase the productivity. Specifically, a polysilicon layer or a metal electrode layer, which has been used as a storage capacitor lower electrode, is replaced by a pixel electrode layer to thereby eliminate a selective doping step onto the polysilicon layer. Specifically, a pixel electrode is formed lower than a gate insulating film and above a glass substrate, and the pixel electrode serves also as a capacitor lower electrode, thereby reducing the number of steps of patterning process from eight steps to seven steps compared with an LTPS TFT LCD of related arts. Further, the use of a single channel structure as in an a-Si TFT LCD rather than a complementary MOS (CMOS) structure further reduces the number of steps of patterning process to six steps.

Further, the embodiments of the present invention can significantly reduce the number of manufacturing steps of a semi-transmissive LCD. Specifically, in a semi-transmissive LCD which conventionally requires a larger number of patterning steps than a transmissive LCD, a reflective electrode is replaced by a wiring layer rather than overlapped with a transmissive electrode to thereby allowing the number of patterning steps to be the same as that of a transmissive LCD. The active matrix display of the embodiments may be applied not only to an LCD but also to other active matrix displays such as an AMOLED.

Exemplary embodiments of the present invention are described hereinafter in detail with reference to the drawings. The present invention, however, is not limited to the following embodiments. The following description and drawings may be appropriately omitted or simplified to clarify the description.

### First Embodiment

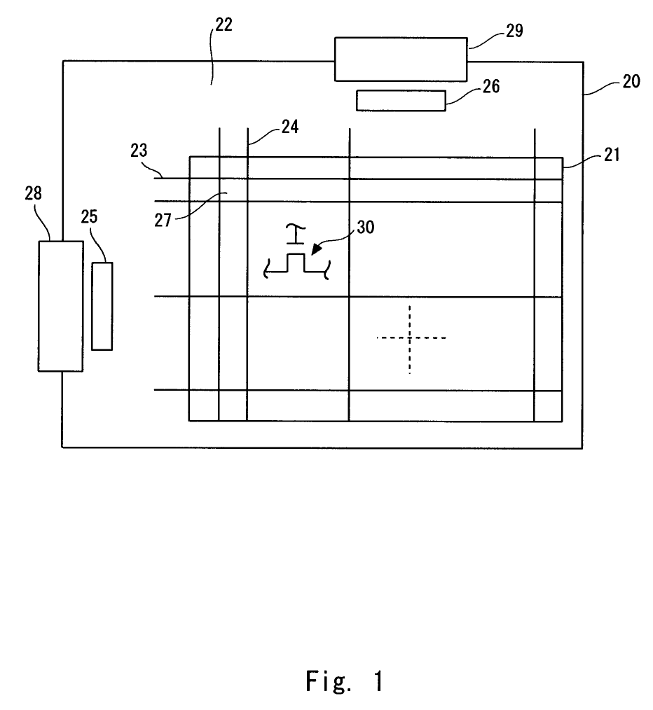

An active matrix display according to a first embodiment of the present invention is described hereinafter with reference to FIG. 1. FIG. 1 is a plan view showing the structure of an active matrix display according to the first embodiment of the present invention.

The display of this embodiment includes a thin film transistor array substrate (which is referred to hereinafter as a TFT array substrate) 20. The TFT array substrate 20 includes a display area 21 and a frame area 22 that surrounds the display area 21. In the display area 21, a plurality of scan signal lines 23 and a plurality of display signal lines 24 are placed. The plurality of scan signal lines 23 are arranged in parallel with each other. The plurality of display signal lines 24 are also arranged in parallel with each other. The scan signal lines 23 and the display signal lines 24 are orthogonal to each other. An area surrounded by the scan signal lines 23 and the display signal lines 24 is a pixel 27. Accordingly, the pixels 27 are arranged in matrix on the TFT array substrate 20.

In the frame area 22 of the TFT array substrate 20, a scan signal driver 25 and a display signal driver 26 are placed. The scan signal line 23 lies from the display area 21 to the frame area 22. The display signal line 24 also lies from the display area 21 to the frame area 22. The display signal line 24 is connected with the display signal driver 26 at an end of the TFT array substrate 20. An external line 28 is connected in the vicinity of the scan signal driver 25. An external line 29 is connected in the vicinity of the display signal driver 26. The external lines 28 and 29 may be wiring boards such as flexible printed circuits (FPCs). The external lines 28 and 29 can be eliminated or shortened according to the systems of the scan signal driver 25 and the display signal driver 26.

External signals are supplied to the scan signal driver 25 and the display signal driver 26 through the external lines 28 and 29. The scan signal driver 25 supplies a scan signal to the scan signal lines 23 according to an external control signal. The scan signal lines 23 are sequentially selected by the scan signal. The display signal driver 26 supplies a display signal to the display signal lines 24 according to an external control signal or display data. A display voltage in accordance with the display data is thereby supplied to each pixel 27. The scan signal driver 25 and the display signal driver 26 are not necessarily placed on the TFT array substrate 20. Instead, the drivers may be connected by tape career package (TCP) or the like.

In an organic EL display, a common line (not shown) for supplying a common voltage and a power supply voltage line (not shown) for supplying a power supply voltage are placed in addition to the scan signal lines 23 and the display signal lines 24. The common line and the power supply voltage line also lie from the display area 21 to the frame area 22 just like the scan signal lines 23 and the display signal lines 24. It is thereby possible to supplies a common voltage and a power supply voltage from the outside to the pixel 27.

In the pixel 27, at least one thin film transistor (TFT) 30 is placed. If, for example, the TFT 30 is a driving TFT for supplying a drive current to an organic EL light emitting element, the organic EL light emitting element is connected with the drain of the TFT 30. Specifically, a pixel electrode is connected with the drain of the TFT 30. A scan signal is supplied to the gate of the TFT 30. Further, an output of a driving TFT (not shown) for supplying a pixel current is connected with the source of the TFT 30. A counter electrode is placed face to face with the pixel electrode. An organic light emitting layer is placed between the pixel electrode and the counter electrode, thereby constituting an organic EL light emitting element. A common voltage is supplied to the counter electrode. In this manner, the pixel electrode and the counter electrode are placed with the organic light emitting layer interposed therebetween. The TFT 30 thus serves as a control element for scanning a drive current flowing through the organic light emitting layer.

The TFT 30 supplies a drive current according to display luminance to the organic EL light emitting element by the scan signal. The scan signal sequentially selects the scan signal lines 23 one by one. At the timing when the TFT 30 turns on, the display signal line 24 supplies a display voltage corresponding to the relevant pixel. The driving TFT (not shown) supplies a prescribed drive current corresponding to the display data for each pixel through the TFT 30. The organic light emitting element thereby emits light at the luminance corresponding to the display data. The scan signal lines 23 are sequentially scanned by the scan signal, thereby displaying a desired image on the display area 21.

In a liquid crystal display, one TFT 30 is placed in the pixel 27. Each TFT is placed in close proximity to the crossing point between the scan signal line 23 and the display signal line 24. The TFT 30 supplies a display voltage to a pixel electrode, for example. Specifically, the TFT 30, which serves as a switching element, turns on by the scan signal from the scan signal line 23. A display voltage is thereby applied from the display signal line 24 to the pixel electrode that is connected with the drain electrode of the TFT 30. An electric field corresponding to the display voltage thereby occurs between the pixel electrode and the counter electrode. An alignment film (not shown) is placed on the surface of the TFT array substrate 20.

Further, a counter substrate is placed opposite to the TFT array substrate 20. The counter substrate may be a color filter substrate, which is placed on the viewing side. A color filter, a black matrix (BM), a counter electrode, an alignment film and so on are placed on the counter substrate. The counter electrode may be placed on the TFT array substrate 20 rather than on the counter substrate. A liquid crystal layer is placed between the TFT array substrate 20 and the counter substrate. In other words, liquid crystals are injected between the TFT array substrate 20 and the counter substrate. Further, a polarizing plate, a phase difference plate and so on are placed at the outer sides of the the TFT array substrate 20 and the counter substrate. Further, a backlight unit or the like is placed at the non-viewing side of the liquid crystal display panel.

The liquid crystals are activated by the electric field between the pixel electrode and the counter electrode. The orientation of the liquid crystals between the substrates thereby changes. As a result, the polarization state of the light passing through the liquid crystal layer changes accordingly. Specifically, the light from the backlight unit or the light from the outside become linearly polarized light by the polarizing plate. The polarization state of the linearly polarized light changes by passing through the liquid crystal layer.

The amount of light to pass through the polarizing plate at the counter substrate side thereby varies according to the polarization state. Specifically, the amount of transmitted light that transmits through the liquid crystal panel or reflected light that is reflected by the liquid crystal display panel to pass through the polarizing plate at the viewing side varies. The orientation of the liquid crystals changes by an applied display voltage. Therefore, the amount of light to pass through the polarizing plate at the viewing side can be changed by controlling a display voltage. Thus, a desired image can be displayed by providing a different display voltage for each pixel. Any of transmissive, semi-transmissive, and reflective types of LCD may be used.

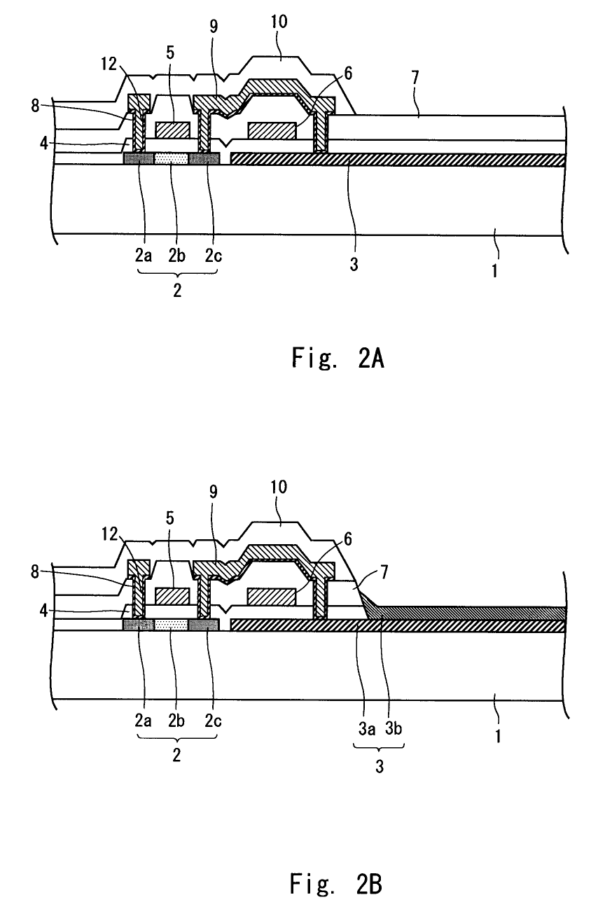

The active matrix display having such a structure is described hereinafter in further detail. FIGS. 2A and 2B are cross-sectional views showing the structure of a TFT and a capacitor portion as a part of the active matrix display according to the first embodiment of the present invention.

As shown in FIG. 2A, a polysilicon layer 2 is placed in a prescribed area of an insulating substrate 1. A source region 2a and a drain region 2c are placed in the polysilicon layer 2, and a channel region 2b is placed between the source region 2a and the drain region 2c. Further, a pixel electrode 3 that is made of a conductive layer is placed separately on the insulating substrate 1. A gate insulating layer 4 is placed on the polysilicon layer 2 and the pixel electrode 3.

Further, a gate electrode 5 is placed above the channel region 2b with the gate insulating layer 4 interposed therebetween. Thus, the gate electrode 5 faces the channel region 2b of the polysilicon layer 2 with the gate insulating layer 4 placed therebetween. For the self-alignment of the gate electrode 5 and the channel region 2b, it is preferred to form the gate electrode 5 and then form the source region 2a and the drain region 2c by selective ion injection using the gate electrode 5 as a mask.

A capacitor upper electrode 6 is placed at a prescribed area above the pixel electrode 3 in the same layer as the gate electrode 5 with the gate insulating layer 4 interposed therebetween. In this embodiment, a part of the pixel electrode 3 serves as a capacitor lower electrode, and a part of the gate insulating layer 4 located thereabove serves as a capacitor insulating film. The part of the pixel electrode 3, the part of the gate insulating layer 4 and the capacitor upper electrode 6 constitute a capacitor. In this manner, the capacitor upper electrode 6 is placed above the pixel electrode 3 with the gate insulating layer 4 interposed therebetween, so that a part of the pixel electrode 3 serves as a capacitor lower electrode. The capacitor upper electrode 6 can be formed at the same time as the gate electrode 5, which simplifies the manufacturing process. Further, the use of a material or thickness different from the gate insulating layer 4 as a capacitor insulating film enables a change in capacitance.

An interlayer insulating layer 7 is placed above the gate electrode 5 and the capacitor upper electrode 6. The interlayer insulating layer 7 has a contact hole 12 that penetrates the interlayer insulating layer 7 and is connected to prescribed positions of the source region 2a, the drain region 2c and the pixel electrode 3. A wiring layer 9 is buried at the upper part of the contact hole 12 to establish electrical connection. Further, an upper insulating layer 10 to cover the wiring layer 9 is placed thereon.

The wiring layer 9 is preferably made of a metal film with high electrical conductivity such as Al. It is also preferred to place an interface conductive film 8 at the interface in order to enhance the electrical connection of the wiring layer 9. Specifically, the interface conductive film 8 is placed at the interface under the wiring layer 9. The interface conductive film 8 is preferably made of a high melting point metal such as Ti, Cr, Zr, Ta, W, Mo, TiN, ZrN, TaN, WN or VN or a metal compound containing at least one of those metals. The upper insulating layer 10 that covers the wiring layer 9 is used to prevent the leakage between a layer for display to be placed thereabove and the wiring layer 9, which may be eliminated depending on the structure of the display.

If the gate insulating layer 4 and the interlayer insulating layer 7 above the pixel electrode 3 are removed, an electric field applied to the liquid crystals that are filled between the pixel electrode 3 and the counter electrode increases to improve the image quality. In a light emitting display of a transmissive LCD, the pixel electrode 3 may be a transparent electrode such as ITO, IZO, or ITZO.

In a light emitting display of a reflective LCD, the pixel electrode 3 may be a reflective electrode such as Al or Ag. If a metal such as Al or Ag is used as a reflective electrode, the crystallization can be promoted during the heat treatment in the subsequent manufacturing process, which can decrease the surface reflectance. As a measure to prevent the degradation of the reflective electrode, it is preferred to form the pixel electrode 3 in a laminated structure by depositing a first pixel electrode 3a and further depositing a second pixel electrode 3b thereon as an upper layer. Specifically, a high melting point metal such as Ti, Cr, Zr, Ta, W, Mo, TiN, ZrN, TaN, WN or VN that is not subjected to heat treatment, or a metal compound containing at least one of those metals may be used as the first pixel electrode 3a. Then, in the step of forming the upper insulating layer 10, the insulating layers above the first pixel electrode 3a, including the upper insulating layer 10, are removed. After that, a reflective electrode such as Al or Ag is formed as the second pixel electrode 3b. The number of patterning steps increases by one in this case.

When using the pixel electrode 3 in such a laminated structure, it is preferred to use a film with high visible light reflectance as the second pixel electrode 3b to be formed on top of the first pixel electrode 3a. The reflectance of Al and Ag at the wavelength of 500 nm are 91.8% and 97.7% (Chronological Science Tables, National Astronomical Observatory ed., Maruzen Co., Ltd.), respectively, which are thus preferred as a material of the second pixel electrode 3b.

When Al, Ag, or an alloy film of them is used as the second pixel electrode 3b, a protective film for the function of carrier injection or the prevention of surface deterioration is required, and it is thus necessary to assume a decrease in reflectance by about 10%. The first pixel electrode 3a and the second pixel electrode 3b are not necessarily overlapped in a wide area as shown in FIG. 2B, and they may be overlapped to the extent that maintains an electrical connection, which is advantageous when a smooth pixel electrode surface with small roughness is required as in an organic EL or the like.

In a light emitting display of an organic EL or the like, it is necessary to remove the gate insulating layer 4 and the interlayer insulating layer 7 above the pixel electrode 3. The gate insulating layer 4 and the interlayer insulating layer 7 above the pixel electrode 3 may be removed at the same time as removing the upper insulating layer 10. In a top emission light emitting display of an organic EL or the like, a reflective electrode such as Al or Ag may be used as the pixel electrode 3 as in the reflective LCD. In a bottom emission light emitting display of an organic EL or the like, a transparent electrode such as ITO, IZO, or ITZO may be used as the pixel electrode 3 as in the transmissive LCD.

A method of manufacturing a TFT and a capacitor portion as a part of the active matrix display according to the first embodiment of the present invention is described hereinbelow.

An amorphous silicon layer is formed at a prescribed position on the insulating substrate 1 such as a transparent glass substrate. Then, laser light is applied to an area of the amorphous silicon layer to become the polysilicon layer 2 for annealing. Upon application of the laser light, the amorphous silicon layer is polycrystallized to thereby form the polysilicon layer 2. An excimer laser or YAG laser may be used as a laser. Alternatively, a Continuous-Wave (CW) laser or a pulse laser may be used. The laser light may be applied to the entire surface of the polysilicon layer 2 or to only a necessary area of the polysilicon layer 2. Specifically, laser light may be applied only to the amorphous silicon layer which remains after the subsequent patterning step. Thermal annealing may be performed instead of laser annealing.

As a result of the annealing, the amorphous silicon layer is melted and crystallized. After the annealing, the polysilicon layer 2 having a prescribed pattern is formed by photolithography. After forming the polysilicon layer 2 by patterning, the pixel electrode 3 is formed. Further, the gate insulating layer 4 is formed so as to cover the pixel electrode 3 in the same layer as the polysilicon layer 2. The gate insulating layer 4 maybe formed by CVD, for example. It is important for the gate insulating layer 4 not to create a trap level of an electron or a positive hole at the interface with the polysilicon layer 2.

Further, a metal or impurity doped polysilicon layer, for example, is formed on the gate insulating layer 4, and the gate electrode 5 is formed above the area corresponding to the channel region 2b of the polysilicon layer 2 and, at the same time, the capacitor upper electrode 6 is formed in the same layer as the gate electrode 5 above a part of the pixel electrode 3. For example, aluminum or an aluminum alloy may be deposited and then patterned by photolithography, thereby forming the gate electrode 5 on the gate insulating layer 4. The pattern of the gate electrode 5 is located above the channel region 2b of the polysilicon layer 2. Although the gate insulating layer 4 is used as a capacitor insulating film in this embodiment, it is possible to change the capacitance by using a material or film thickness different from the gate insulating layer 4. The capacitor upper electrode 6 may be formed at the same time as the gate electrode 5, which simplifies the manufacturing process.

After that, P (phosphorus) or As (arsenic) is injected into the polysilicon layer 2 through the gate electrode 5 and the gate insulating layer 4 to thereby form the source and drain regions. Further, the interlayer insulating layer 7 is formed. They may be formed by normal photolithography process. After forming the interlayer insulating layer 7, the contact hole 12 is created. The contact hole 12 is created so as to expose the source region 2a and the drain region 2c. Further, the wiring layer 9 is deposited on the interlayer insulating layer 7. The wiring layer 9 is preferably a metal film with high electric conductivity such as Al. It is preferred to form the interface conductive film 8 to enhance the electrical connection of the wiring layer 9. Preferably, the interface conductive film 8 is made of a high melting point metal such as Ti, Cr, Zr, Ta, W, Mo, TiN, ZrN, TaN, WN or VN or a metal compound containing at least one of those metals. After that, the upper insulating layer 10 to cover the wiring layer 9 is formed. The upper insulating layer 10 is used to prevent the leakage between a layer for display to be formed thereabove and the wiring layer 9, which may be eliminated depending on the structure of the display.

As described earlier, with the structure where the gate insulating layer 4 and the interlayer insulating layer 7 above the pixel electrode 3 are removed, an electric field that is applied to the liquid crystals that are filled between the pixel electrode 3 and the counter electrode increases to thereby improve the image quality. In a light emitting display of an organic EL or the like, it is necessary to remove the insulating film above the pixel electrode 3. In such a case, the gate insulating layer 4 above the pixel electrode 3 may be removed at the same time as removing the upper insulating layer 10.

In such a structure according to this embodiment, the first pixel electrode 3a that is formed lower than the gate insulating layer 4 and the capacitor upper electrode 6 that is formed in the same layer as the gate electrode 5 with the gate insulating layer 4 interposed therebetween constitute a capacitor. The first pixel electrode 3a thus serves also as a capacitor lower electrode and the capacitor upper electrode 6 is formed at the same time as the gate electrode 5, thereby reducing the number of steps of the manufacturing process of the display and permitting the design and manufacturing of pixels in various layouts. Further, the pixel electrode 3 is formed in a laminated structure, thereby suppressing the degradation of the reflective electrode.

As described in Yudasaka, if the source line and the pixel electrode are formed in the same layer, a DC voltage is constantly applied to a liquid crystal layer because of a difference in average voltage between the source line and the pixel electrode, which causes a decrease in reliability of a display. According to this embodiment, the source line and the pixel electrode are formed in different layers, thereby maintaining the reliability of the display.

### Second Embodiment

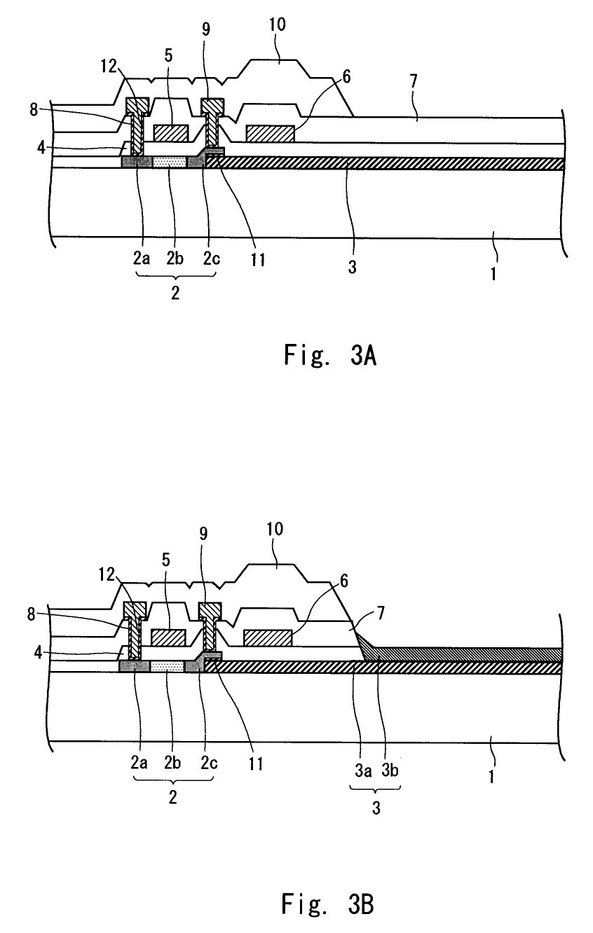

An active matrix display according to a second embodiment of the present invention is described hereinafter with reference to FIGS. 3a and 3b. FIGS. 3a and 3b are cross-sectional views showing the structure of a TFT and a capacitor portion as a part of the active matrix display according to the second embodiment of the present invention.

The active matrix display of this embodiment shown in FIG. 3A is different from the active matrix display of the first embodiment shown in FIG. 2A in that the pixel electrode 3 is connected under the polysilicon layer 2. Specifically, the drain region 2c of the polysilicon layer 2 is placed on the pixel electrode 3 so that it is partly overlapped with the pixel electrode 3. Therefore, the polysilicon layer 2 is formed after the pixel electrode 3 is formed. In this structure, the insulating substrate 1 is preferably such that a protective insulating layer is placed on a glass substrate or a conductive substrate.

Specifically, the pixel electrode 3 is placed in a prescribed area on the insulating substrate 1 and the polysilicon layer 2 is placed so as to cover a part of the pixel electrode 3. In the polysilicon layer 2, the drain region 2c is formed to cover the pixel electrode 3, the source region 2a is formed opposite to the drain region 2c, and the channel region 2b is placed between the source region 2a and the drain region 2c.

The gate insulating layer 4 is formed on the polysilicon layer 2 that partly covers the pixel electrode 3 and the pixel electrode 3. Further, the gate electrode 5 is formed above the channel region 2b with the gate insulating layer 4 interposed therebetween.

The capacitor upper electrode 6 is formed in a prescribed area above the pixel electrode 3 in the same layer as the gate electrode 5 with the gate insulating layer 4 interposed therebetween. A part of the pixel electrode 3 serves as a capacitor lower electrode, and the gate insulating layer 4 located thereabove serves as a capacitor insulating film. The part of the pixel electrode 3, the gate insulating layer 4 and the capacitor upper electrode 6 constitute a capacitor. In this manner, as in the first embodiment, the capacitor upper electrode 6 is placed above the pixel electrode 3 with the gate insulating layer 4 interposed therebetween, so that a part of the pixel electrode 3 serves as a capacitor lower electrode. The capacitor upper electrode 6 can be formed at the same time as the gate electrode 5, which simplifies the manufacturing process.

An interlayer insulating layer 7 is formed above the gate electrode 5 and the capacitor upper electrode 6. The interlayer insulating layer 7 has a contact hole 12 that penetrates the interlayer insulating layer 7 and is connected to prescribed positions of the source region 2a and the drain region 2c. A wiring layer 9 is buried at the upper part of the contact hole 12 to establish electrical connection. Because the drain region 2c of the polysilicon layer 2 and the pixel electrode 3 that serves also as a capacitor lower electrode are directly connected already, there is no need to connect the wiring layer 9 through the contact hole 12. Further, an upper insulating layer 10 to cover the wiring layer 9 is formed thereon.

The upper insulating layer 10 that covers the wiring layer 9 is used to prevent the leakage between a layer for display to be placed thereabove and the wiring layer 9, and it may be eliminated depending on the structure of the display. With the use of a structure where the gate insulating layer 4 and the interlayer insulating layer 7 are removed, an electric field that is applied to the liquid crystals filled between the pixel electrode 3 and the counter electrode increases to thereby improve the image quality.

The polysilicon layer 2 may be formed of low-temperature polysilicon typically by annealing with laser or the like after the formation of an a-Si layer. In other methods also, the pixel electrode 3 and an interface conductive film 11 need to be resistant to heating for the formation of the polysilicon layer 2. Therefore, it is preferred to use a high melting point metal such as Ti, Cr, Zr, Ta, W, Mo, TiN, ZrN, TaN, WN or VN or a metal compound for the interface conductive film 11, particularly.

In a transmissive LCD and a reflective LCD, the pixel electrode 3 can be formed in the same manner as in the first embodiment. However, the pixel electrode 3 can be degraded by heat treatment in the subsequent manufacturing process as described above. To prevent this, the pixel electrode 3 preferably has a laminated structure of the first pixel electrode 3a and the second pixel electrode 3b placed on top of it as shown in FIG. 3B.

When using Al, Ag, or an alloy film of them as the second pixel electrode 3b, a protective film for the function of carrier injection or the prevention of surface deterioration is required, and it is thus necessary to assume a decrease in reflectance by about 10%. The first pixel electrode 3a and the second pixel electrode 3b are not necessarily overlapped in a wide area as shown in FIG. 3B, and they may be overlapped to the extent that maintains an electrical connection, which is advantageous when a smooth pixel electrode surface with small roughness is required as in an organic EL or the like. It is the same as in the first embodiment for a light emitting display of an organic EL or the like.

A method of manufacturing a TFT and a capacitor portion as a part of the active matrix display according to the second embodiment of the present invention is described hereinbelow. The manufacturing method of this embodiment is different from the manufacturing method of the first embodiment in the sequence of forming the polysilicon layer 2 and the pixel electrode 3 above the insulating substrate 1.

Firstly, the pixel electrode 3 is formed in a prescribed position on the insulating substrate 1. Then, the polysilicon layer 2 is formed to cover a part of the pixel electrode 3. In the polysilicon layer 2, the drain region 2c is formed to cover the pixel electrode 3, the source region 2a is formed opposite to the drain region 2c, and the channel region 2b is placed between the source region 2a and the drain region 2c. In this case, the pixel electrode 3 is made of a material having good electrical characteristics with the polysilicon layer 2 or the interface conductive film 11 having good electrical connectivity is placed at the interface. The interface conductive film 11 may be selectively removed at the pattern formation of the polysilicon layer using the polysilicon layer as a mask. The subsequent manufacturing process is the same as that of the first embodiment.

In this embodiment having the above configuration also, a capacitor is composed of the first pixel electrode 3a that is formed in a lower layer than the gate insulating layer 4 and the capacitor upper electrode 6 that is formed in the same layer as the gate electrode 5 with the gate insulating layer 4 interposed therebetween, thereby having the same advantage as in the first embodiment. Further, because the polysilicon layer 2 is partly overlapped with the pixel electrode 3 , the drain region 2c of the polysilicon layer 2 and the pixel electrode 3 are directly connected, thereby eliminating the need for connecting the wiring layer 9 through a contact hole.

Further, this embodiment allows the source line and the pixel electrode to be in different layers as in the first embodiment, thereby maintaining the reliability of the display.

### Third Embodiment

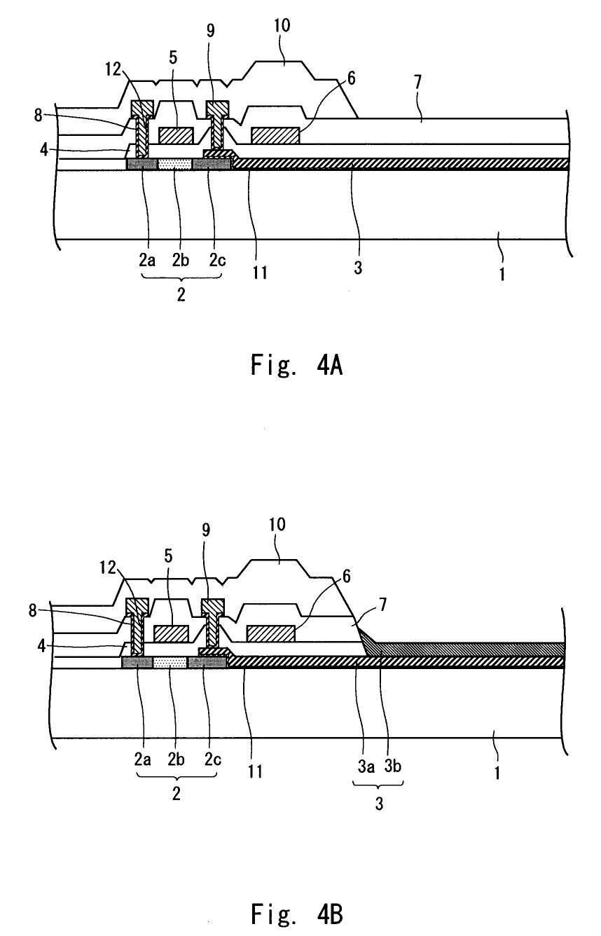

An active matrix display according to a third embodiment of the present invention is described hereinafter with reference to FIGS. 4a and 4b. FIGS. 4a and 4b are cross-sectional views showing the structure of a TFT and a capacitor portion as a part of the active matrix display according to the third embodiment of the present invention.

The active matrix display of this embodiment shown in FIG. 4A is different from the active matrix display of the second embodiment shown in FIG. 3A in that the pixel electrode 3 is connected on the polysilicon layer 2. Specifically, the pixel electrode 3 is partly overlapped with the drain region 2c of the polysilicon layer 2, and the pixel electrode 3 is formed after the polysilicon layer 2 is formed. In this structure, the insulating substrate 1 is preferably such that a protective insulating layer is placed on a glass substrate or a conductive substrate.

As shown in FIG. 4A, in the active matrix display of this embodiment, the polysilicon layer 2 is formed in a prescribed area on the insulating substrate 1. The pixel electrode 3 is formed thereabove to partly cover the drain region 2c of the polysilicon layer 2. In the polysilicon layer 2, the source region 2a and the drain region 2c are formed, and the channel region 2b is formed between the source region 2a and the drain region 2c.

Further, the gate insulating layer 4 is formed on the upper surface of the polysilicon layer 2 and the pixel electrode 3 that covers a part of the drain region 2c of the polysilicon layer 2.

The gate electrode 5 is formed above the channel region 2b with the gate insulating layer 4 interposed therebetween. The gate electrode 5 is thus placed opposite to the channel region 2b of the polysilicon layer 2 with the gate insulating layer 4 interposed therebetween. For the self-alignment of the gate electrode 5 and the channel region 2b, it is preferred to form the gate electrode 5 and then form the source region 2a and the drain region 2c by selective ion injection using the gate electrode 5 as a mask.

At the selective ion injection, the pixel electrode 3 that partly covers the drain region 2c of the polysilicon layer 2 hinders the ion injection. Particularly, the depth of phosphorus ion injection to form an n-type region is about ⅓ of the depth of boron ion injection to form a p-type region with the same injection energy, and thus the ion injection is difficult. At the phosphorus ion injection, it is preferred that the gate insulating film of a target area is 30 nm or smaller, the pixel electrode film thickness is 80 nm or smaller, the interface conductive film is 20 nm or smaller, and the phosphorus ion injection energy is 100 keV. The pixel electrode 3 is preferably made of a material with a relatively low ion stopping power, and it is preferred to contain ITO for a transparent electrode, Al, Ti or Zr for a non-transparent electrode, and Ti, Zr, or a conductive Ti—Zr compound for the interface conductive film 11. It is also preferred to remove the pixel electrode 3 in the vicinity of the gate electrode 5 so that the phosphorus ion can sufficiently reach the polysilicon layer. If the drain region 2c is formed under such conditions, the drain resistance is compensated by the conductivity of the pixel electrode 3 even when the substantial amount of injection to the drain region 2c below the pixel electrode 3 is small, thereby eliminating an obstacle in the TFT characteristics.

The capacitor upper electrode 6 is formed in a prescribed area above the pixel electrode 3 in the same layer as the gate electrode 5 with the gate insulating layer 4 interposed therebetween. A part of the pixel electrode 3 serves as a capacitor lower electrode, and the gate insulating layer 4 located thereabove serves as a capacitor insulating film. The part of the pixel electrode 3, the gate insulating layer 4 and the capacitor upper electrode 6 constitute a capacitor. In this manner, as in the first embodiment, the capacitor upper electrode 6 is placed above the pixel electrode 3 with the gate insulating layer 4 interposed therebetween, so that a part of the pixel electrode 3 serves as a capacitor lower electrode. The capacitor upper electrode 6 can be formed at the same time as the gate electrode 5, which simplifies the manufacturing process.

An interlayer insulating layer 7 is formed above the gate electrode 5 and the capacitor upper electrode 6. The interlayer insulating layer 7 has a contact hole 12 that penetrates the interlayer insulating layer 7 and is connected to prescribed positions of the source region 2a and the drain region 2c. The wiring layer 9 is buried at the upper part of the contact hole 12, so that the source region 2a is directly connected with the wiring layer 9, and the drain region 2c is electrically connected with the wiring layer 9 through the pixel electrode 3. Because the drain region 2c of the polysilicon layer 2 and the pixel electrode 3 that serves also as a capacitor lower electrode are directly connected with the wiring layer 9, there is no need to connect the wiring layer 9 through a contact hole. Further, an upper insulating layer 10 to cover the wiring layer 9 is formed thereon.

The upper insulating layer 10 that covers the wiring layer 9 is used to prevent the leakage between a layer for display to be placed thereabove and the wiring layer 9, and it may be eliminated depending on the structure of the display. With the use of a structure where the gate insulating layer 4 and the interlayer insulating layer 7 above the pixel electrode 3 are removed, an electric field that is applied to the liquid crystals filled between the pixel electrode 3 and the counter electrode increases to thereby improve the image quality.

In a transmissive LCD and a reflective LCD, the pixel electrode 3 can be formed in the same manner as in the first embodiment and the second embodiment. However, the pixel electrode 3 can be degraded by heat treatment in the subsequent manufacturing process as described above. To prevent this, the pixel electrode 3 preferably has a laminated structure of the first pixel electrode 3a and the second pixel electrode 3b placed on top of it as shown in FIG. 4B.

When using Al, Ag, or an alloy film of them as the second pixel electrode 3b, a protective film for the function of carrier injection or the prevention of surface deterioration is required, and it is thus necessary to assume a decrease in reflectance by about 10%. The first pixel electrode 3a and the second pixel electrode 3b are not necessarily overlapped in a wide area as shown in FIG. 4B, and they may be overlapped to the extent that maintains an electrical connection, which is advantageous when a smooth pixel electrode surface with small roughness is required as in an organic EL or the like. It is the same as in the first embodiment for a light emitting display of an organic EL or the like.

A method of manufacturing a TFT and a capacitor portion as a part of the active matrix display according to the third embodiment of the present invention is described hereinbelow. The manufacturing method of this embodiment is different from the manufacturing method of the first embodiment in the sequence of forming the polysilicon layer 2 and the pixel electrode 3 above the insulating substrate 1.

Firstly, the polysilicon layer 2 is formed in a prescribed position on the insulating substrate 1. Then, the pixel electrode 3 is formed to cover apart of the drain region 2c of the polysilicon layer 2. In this case, the pixel electrode 3 is made of a material having good electrical characteristics with the polysilicon layer 2 or the interface conductive film 11 having good electrical connectivity is placed at the interface. The interface conductive film 11 may be selectively removed at the pattern formation of the polysilicon layer using the polysilicon layer as a mask. The subsequent manufacturing process is the same as that of the first embodiment.

In the third embodiment, at the selective ion injection into the semiconductor film, the pixel electrode 3 that partly covers the drain region 2c of the polysilicon layer 2 hinders the ion injection. Particularly, the depth of phosphorus ion injection to form an n-type region is about ⅓ of the depth of boron ion injection to form a p-type region with the same injection energy, and the ion injection is difficult. At the phosphorus ion injection, it is preferred that the gate insulating film of a target area is 30 nm or smaller, the pixel electrode film thickness is 80 nm or smaller, the interface conductive film is 20 nm or smaller, and the phosphorus ion injection energy is 100 keV. The pixel electrode 3 is preferably made of a material with a relatively low ion stopping power, and it is preferred to contain ITO for a transparent electrode, Al, Ti or Zr for a non-transparent electrode, and Ti, Zr, or a conductive Ti—Zr compound for the interface conductive film. It is also preferred to remove the pixel electrode 3 in the vicinity of the gate electrode 5 so that the phosphorus ion can sufficiently reach the polysilicon layer. If the drain region 2c is formed under such conditions, the drain resistance is compensated by the conductivity of the pixel electrode 3 even when the substantial amount of injection to the drain region 2c below the pixel electrode 3 is small, thereby eliminating an obstacle in the TFT characteristics.

In this embodiment having the above configuration also, a capacitor is composed of the first pixel electrode 3a that is formed in a lower layer than the gate insulating layer 4 and the capacitor upper electrode 6 that is formed in the same layer as the gate electrode 5 with the gate insulating layer 4 interposed therebetween, thereby having the same advantage as in the first embodiment. Further, because the pixel electrode 3 is partly overlapped with the polysilicon layer 2, the drain region 2c of the polysilicon layer 2 and the pixel electrode 3 are directly connected, thus eliminating the need for connecting the wiring layer 9 through a contact hole.

Further, this embodiment allows the source line and the pixel electrode to be in different layers as in the first embodiment, thereby maintaining the reliability of the display.

### Fourth Embodiment

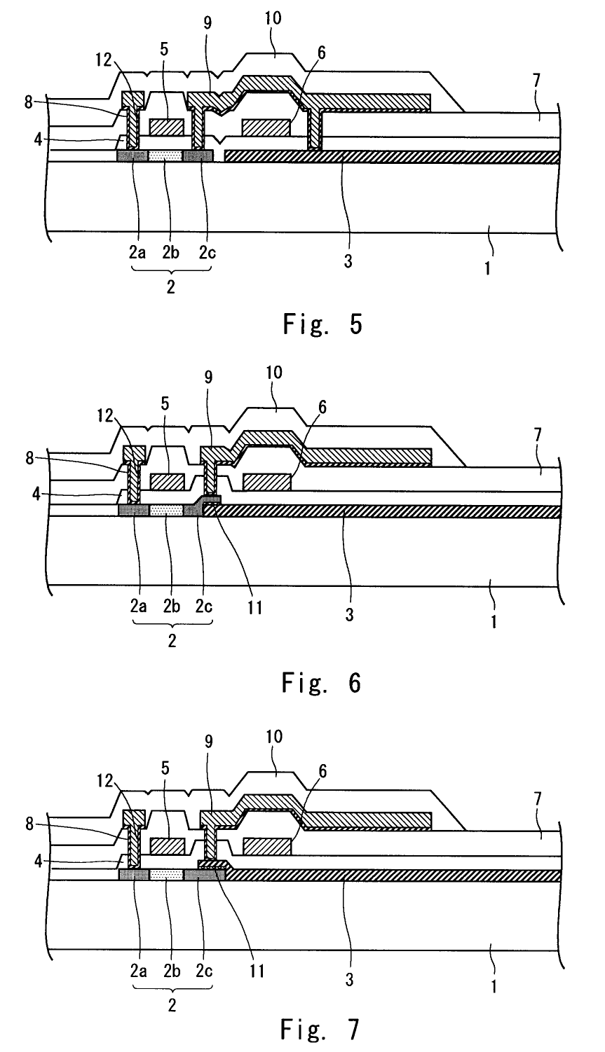

An active matrix display according to a fourth embodiment of the present invention is described hereinafter with reference to FIG. 5. FIG. 5 is a cross-sectional view showing the structure of a TFT and a capacitor portion as a part of the active matrix display according to the fourth embodiment of the present invention.

The structure of FIG. 5 is the same as the structure of FIG. 2A except for the wiring layer 9 and the upper insulating layer 10. The same reference numeral indicates the same layer. The wiring layer 9 extends to a part of the pixel area and serves as a pixel reflective electrode. The wiring layer 9 is preferably a metal film with high electrical conductivity such as Al. It is also preferred to place the interface conductive film 8 at the interface of the first pixel electrode 3a and the polysilicon layer 2 in order to enhance the electrical connection of the wiring layer 9.

The upper insulating layer 10 that covers the wiring layer 9 is used to prevent the leakage between a layer for display to be placed thereabove and the wiring layer 9, and it may be eliminated depending on the structure of the display. With the use of a structure where the gate insulating layer 4 and the interlayer insulating layer 7 above the pixel electrode 3 are removed, an electric field that is applied to the liquid crystals filled between the pixel electrode 3 and the counter electrode increases to thereby improve the image quality. Further, the source line and the pixel electrode may be placed in different layers, thereby maintaining the reliability of the display.

In this embodiment having the above configuration also, a capacitor is composed of the first pixel electrode 3a that is formed in a lower layer than the gate insulating layer 4 and the capacitor upper electrode 6 that is formed in the same layer as the gate electrode 5 with the gate insulating layer 4 interposed therebetween, thereby having the same advantage as in the first embodiment. Further, because the wiring layer 9 is formed to cover a part of the pixel area, so that the wiring layer 9 serves as a pixel reflective electrode. The above structure is thus suitable for a semi-transmissive liquid crystal display.

Further, this embodiment allows the source line and the pixel electrode to be in different layers as in the first embodiment, thereby maintaining the reliability of the display.

### Fifth Embodiment

An active matrix display according to a fifth embodiment of the present invention is described hereinafter with reference to FIG. 6. FIG. 6 is a cross-sectional view showing the structure of a TFT and a capacitor portion as a part of the active matrix display according to the fifth embodiment of the present invention.

The structure of FIG. 6 is the same as the structure of FIG. 3A except for the wiring layer 9 and the upper insulating layer 10. The same reference numeral indicates the same layer. The wiring layer 9 extends to a part of the pixel area and serves as a pixel reflective electrode. The wiring layer 9 is preferably a metal film with high electrical conductivity such as Al. It is also preferred to place the interface conductive film 8 at the interface of the polysilicon layer 2 in order to enhance the electrical connection of the wiring layer 9.

The upper insulating layer 10 that covers the wiring layer 9 is used to prevent the leakage between a layer for display to be placed thereabove and the wiring layer 9, and it may be eliminated depending on the structure of the display. With the use of a structure where the gate insulating layer 4 and the interlayer insulating layer 7 above the pixel electrode 3 are removed, an electric field that is applied to the liquid crystals filled between the pixel electrode 3 and the counter electrode increases to thereby improve the image quality.

In this embodiment having the above configuration also, a capacitor is composed of the first pixel electrode 3a that is formed in a lower layer than the gate insulating layer 4 and the capacitor upper electrode 6 that is formed in the same layer as the gate electrode 5 with the gate insulating layer 4 interposed therebetween, thereby having the same advantage as in the first embodiment. Further, because the polysilicon layer 2 is partly overlapped with the pixel electrode 3, the drain region 2c of the polysilicon layer 2 and the pixel electrode 3 are directly connected to each other, thus eliminating the need for connecting the wiring layer 9 through a contact hole. Furthermore, the wiring layer 9 extends to a part of the pixel area, so that the wiring layer 9 can serve as a pixel reflective electrode. The above structure is thus suitable for a semi-transmissive liquid crystal display.

In addition, this embodiment allows the source line and the pixel electrode to be in different layers as in the first embodiment, thereby maintaining the reliability of the display.

### Sixth Embodiment

An active matrix display according to a sixth embodiment of the present invention is described hereinafter with reference to FIG. 7. FIG. 7 is a cross-sectional view showing the structure of a TFT and a capacitor portion as a part of the active matrix display according to the sixth embodiment of the present invention.

The structure of FIG. 7 is the same as the structure of FIG. 4A except for the wiring layer 9 and the upper insulating layer 10. The same reference numeral indicates the same layer. The wiring layer 9 extends to a part of the pixel area and serves as a pixel reflective electrode. The wiring layer 9 is preferably a metal film with high electrical conductivity such as Al. It is also preferred to place the interface conductive film 8 at the interface of the polysilicon layer 2 and the pixel electrode 3 in order to enhance the electrical connection of the wiring layer 9.

The upper insulating layer 10 that covers the wiring layer 9 is used to prevent the leakage between a layer for display to be placed thereabove and the wiring layer 9, and it may be eliminated depending on the structure of the display. With the use of a structure where the gate insulating layer 4 and the interlayer insulating layer 7 above the pixel electrode 3 are removed, an electric field that is applied to the liquid crystals filled between the pixel electrode 3 and the counter electrode increases to thereby improve the image quality. Further, the source line and the pixel electrode may be placed in different layers as in the first embodiment, thereby maintaining the reliability of the display.

In this embodiment having the above configuration also, a capacitor is composed of the first pixel electrode 3a that is formed in a lower layer than the gate insulating layer 4 and the capacitor upper electrode 6 that is formed in the same layer as the gate electrode 5 with the gate insulating layer 4 interposed therebetween, thereby having the same advantage as in the first embodiment. Further, because the pixel electrode 3 is partly overlapped with the polysilicon layer 2, the drain region 2c of the polysilicon layer 2 and the pixel electrode 3 are directly connected to each other, thus eliminating the need for connecting the wiring layer 9 through a contact hole. Furthermore, the wiring layer 9 extends to a part of the pixel area, so that the wiring layer 9 can serve as a pixel reflective electrode. The above structure is thus suitable for a semi-transmissive liquid crystal display.

In addition, this embodiment allows the source line and the pixel electrode to be in different layers as in the first embodiment, thereby maintaining the reliability of the display.

### Other Embodiment

Although the low-temperature polysilicon formed by laser annealing is used in the above-described embodiments, it is not limited thereto. The present invention may be applied to an active matrix display using a polysilicon TFT or a microcrystalline silicon TFT that is formed by various other methods. Further, although the TFT structure is described with reference to a self-aligned (SA) TFT in the above embodiments, the same advantages can be obtained with the use of a lightly doped drain (LDD) TFT, a gate-overlapped LDD (GOLD) TFT or the like.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. An active matrix display comprising:
an insulating substrate;
a polysilicon layer including a source region, a drain region and a channel region, placed on the insulating substrate;
a gate insulating layer placed on the polysilicon layer;
a gate electrode placed on the gate insulating layer;
an interlayer insulating layer placed on the gate electrode;
a wiring layer connected to the source region and the drain region through a contact hole of the interlayer insulating layer;
a first pixel electrode placed on the insulating substrate; and
an upper electrode placed in the same layer as the gate electrode, wherein
the first pixel electrode, the gate insulating layer and the upper electrode constitute a capacitor.

2. The active matrix display according to claim 1, wherein
the first pixel electrode is partly placed on the drain region of the polysilicon layer in an overlapping manner.

3. The active matrix display according to claim 1, wherein
the drain region of the polysilicon layer is partly placed on the first pixel electrode in an overlapping manner.

4. The active matrix display according to claim 2, wherein
the first pixel electrode includes a layer of a high melting point metal or a metal compound, or
a layer of a high melting point metal or a metal compound is placed between the first pixel electrode and the polysilicon layer.

5. The active matrix display according to claim 3, wherein
the first pixel electrode includes a layer of a high melting point metal or a metal compound, or
a layer of a high melting point metal or a metal compound is placed between the first pixel electrode and the polysilicon layer.

6. The active matrix display according to claim 4, wherein
the first pixel electrode includes a layer containing at least one material selected from the group of Ti, Cr, Zr, Ta, W, Mo, TiN, ZrN, TaN, WN and VN, or
a layer containing at least one material selected from the group of Ti, Cr, Zr, Ta, W, Mo, TiN, ZrN, TaN, WN and VN is placed between the first pixel electrode and the polysilicon layer.

7. The active matrix display according to claim 5, wherein
the first pixel electrode includes a layer containing at least one material selected from the group of Ti, Cr, Zr, Ta, W, Mo, TiN, ZrN, TaN, WN and VN, or
a layer containing at least one material selected from the group of Ti, Cr, Zr, Ta, W, Mo, TiN, ZrN, TaN, WN and VN is placed between the first pixel electrode and the polysilicon layer.

8. The active matrix display according to claim 1, further comprising:
an upper insulating layer to cover the wiring layer and the interlayer insulating layer, wherein
the gate insulating layer, the interlayer insulating layer, and the upper insulating layer are removed in an area above a part of the first pixel electrode.

9. The active matrix display according to claim 2, wherein
an upper insulating layer to cover the wiring layer and the interlayer insulating layer, wherein
the gate insulating layer, the interlayer insulating layer, and the upper insulating layer are removed in an area above a part of the first pixel electrode.

10. The active matrix display according to claim 3, wherein
an upper insulating layer to cover the wiring layer and the interlayer insulating layer, wherein
the gate insulating layer, the interlayer insulating layer, and the upper insulating layer are removed in an area above a part of the first pixel electrode.

11. The active matrix display according to claim 8, further comprising:
a second pixel electrode electrically connected with the first pixel electrode, placed in the area above the part of the first pixel electrode where the gate insulating layer, the interlayer insulating layer, and the upper insulating layer are removed, wherein
the second pixel electrode has a visible light reflectance of 70% or higher.

12. The active matrix display according to claim 9, wherein
a second pixel electrode electrically connected with the first pixel electrode, placed in the area above the part of the first pixel electrode where the gate insulating layer, the interlayer insulating layer, and the upper insulating layer are removed, wherein
the second pixel electrode has a visible light reflectance of 70% or higher.

13. The active matrix display according to claim 10, wherein
a second pixel electrode electrically connected with the first pixel electrode, placed in the area above the part of the first pixel electrode where the gate insulating layer, the interlayer insulating layer, and the upper insulating layer are removed, wherein
the second pixel electrode has a visible light reflectance of 70% or higher.

14. The active matrix display according to claim 1, wherein
the wiring layer is connected with the drain region and serves as a reflective electrode of a pixel electrode.

15. The active matrix display according to claim 2, wherein
the wiring layer is connected with the drain region and serves as a reflective electrode of a pixel electrode.

16. The active matrix display according to claim 3, wherein
the wiring layer is connected with the drain region and serves as a reflective electrode of a pixel electrode.

17. The active matrix display according to claim 1, wherein
the wiring layer includes a layer of a high melting point metal or a metal compound, or
a layer of a high melting point metal or a metal compound is placed at an interface under the wiring layer.

18. The active matrix display according to claim 17, wherein
the wiring layer includes a layer containing at least one material selected from the group of Ti, Cr, Zr, Ta, W, Mo, TiN, ZrN, TaN, WN and VN, or
a layer containing at least one material selected from the group of Ti, Cr, Zr, Ta, W, Mo, TiN, ZrN, TaN, WN and VN is placed at an interface under the wiring layer.
